(19) United States
(12) Patent Application Publication
(10) Pub. No.: US 2025/0267836 A1
(43) Pub. Date: Aug. 21, 2025

(54) SELF-ALIGNED STORAGE NODE CONTACT IN DYNAMIC RANDOM ACCESS MEMORY (DRAM) DEVICE

(71) Applicant: Applied Materials, Inc., Santa Clara, CA (US)

(72) Inventor: Tong LIU, San Jose, CA (US)

(21) Appl. No.: 18/444,858

(22) Filed: Feb. 19, 2024

(51) Int. Cl. H10B 12/00

(52) U.S. Cl. CPC H10B 12/0335; H10B 12/05; H10B 12/315

(57) ABSTRACT

A method for forming a storage node contact in a dynamic random access memory (DRAM) device includes polishing an array wafer from a top side of the array wafer, the array wafer including a bitline layer, a channel pillar, a word line layer, and a bottom source/drain (S/D) junction that electrically connects the channel pillar to the bitline layer, disposed within a shallow trench isolation (STI), doping a top portion of the channel pillar and forming a top S/D junction, selectively forming an interlayer dielectric (ILD) on the STI versus the top S/D junction, forming an interface layer on an exposed surface of the top S/D junction, depositing a contact metal layer on the ILD and the interface layer, forming a storage node landing pad in the contact metal layer, and filling a gap between the storage node landing pad and an adjacent storage node contact pad with insulator film material.

### BACKGROUND

### Field

Embodiments described herein generally relate to semiconductor device fabrication, and more particularly, to methods of forming a self-aligned storage node contact in 4F² (feature square) dynamic random access memory (DRAM) devices.

### Description of the Related Art

The production of silicon integrated circuits has placed difficult demands on fabrication processes to increase the number of devices while decreasing the minimum feature sizes on a chip. These demands have extended to fabrication processes including depositing layers onto difficult topologies while maintaining device reliability. For example, 4F² (feature square) dynamic random access memory (DRAM) devices may include a storage node contact that requires extreme ultraviolet (EUV) lithography, or double 193 nm immersion self-aligned quadruple patterning (SAQP), for patterning.

Thus, there is a need for improved processes for forming a storage node contact without requiring complex and costly lithography processes during the fabrication.

### SUMMARY

Embodiments of the present disclosure provide a method for forming a storage node contact in a dynamic random access memory (DRAM) device. The method includes performing an array wafer polish process to polish an array wafer from a top side of the array wafer, the array wafer including a bitline layer, a channel pillar over the bitline layer and surrounded by a gate oxide layer, a word line layer on both sides of the channel pillar, and a bottom source/drain (S/D) junction that electrically connects the channel pillar to the bitline layer, disposed within a shallow trench isolation (STI), performing a junction implant and activation process to dope a top portion of the channel pillar and form a top S/D junction, performing a selective dielectric deposition process to selectively form an interlayer dielectric (ILD) on the STI versus the top S/D junction, performing a silicidation process to form an interface layer on an exposed surface of the top S/D junction, performing a contact metal deposition process to deposit a contact metal layer on the ILD and the interface layer, performing a storage node landing pad (SNLP) lithography and etch process to form a storage node landing pad in the contact metal layer, and performing an insulator fill process to fill a gap between the storage node landing pad and an adjacent storage node landing pad with dielectric material.

Embodiments of the present disclosure also provide a method for forming a self-aligned interlayer dielectric (ILD) in a vertical channel structure. The method includes selectively depositing an ILD on a dielectric region versus an exposed surface of a channel pillar disposed within the dielectric region, wherein: the dielectric region includes silicon oxide (SiO₂), and the channel pillar includes silicon (Si).

Embodiments of the present disclosure further provide a vertical channel structure. The vertical channel structure includes a bitline layer extending in a first direction, a word line layer extending in a second direction that is orthogonal to the first direction, a vertical array transistor disposed within a shallow trench isolation (STI), the vertical array transistor including a channel pillar, a bottom source/drain (S/D) junction electrically connected to the bitline layer, and a top S/D junction connectible to a storage capacitor via a storage node contact, wherein the storage node contact includes an interface layer on a surface of the top S/D junction surrounded by a self-aligned interlayer dielectric (ILD) on a surface of the STI, a contact metal layer on the interface layer and the ILD, and a landing pad within the contact metal layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic top view of a multi-chamber cluster tool, according to one embodiment.

FIG. 2 is a process flow diagram of a method of forming a self-aligned storage node contact (SNC) in a vertical channel structure, according to one embodiment.

FIGS. 3A, 3A′, 3B, 3B′, 3C, 3C′, 3D, 3D′, 3E, 3E′, 3F, 3F′, 3G, 3G′, 3H, and 3H′ are schematic views of a portion of a vertical channel structure according to one embodiment.

To facilitate understanding, identical reference numerals have been used, where possible, to designate identical elements that are common to the figures. It is contemplated that elements and features of one embodiment may be beneficially incorporated in other embodiments without further recitation. In the figures and the following description, an orthogonal coordinate system including an X-axis, a Y-axis, and a Z-axis is used. The directions represented by the arrows in the drawings are assumed to be positive directions for convenience. It is contemplated that elements disclosed in some embodiments may be beneficially utilized on other implementations without specific recitation.

### DETAILED DESCRIPTION

Embodiments described herein are directed to methods of forming a self-aligned storage node contact (SNC) in a vertical channel structure used in a 4F² dynamic random access memory (DRAM) device. An interlayer dielectric (ILD) surrounding a surface of a vertical array transistor is formed in a self-aligned process by selective dielectric deposition, and thus fabrication of a storage node contact (SNC) including such ILD does not require complex and costly lithography processes or selective epitaxy growth of silicon.

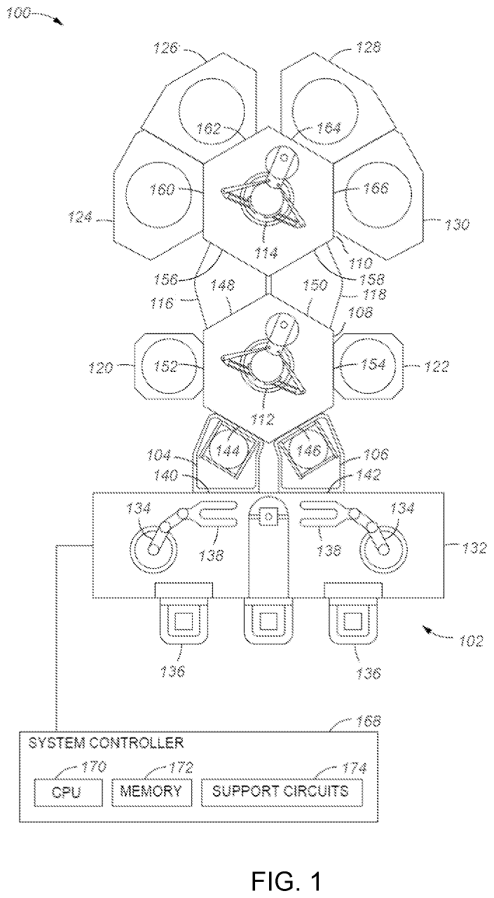

FIG. 1 is a schematic top view of a multi-chamber cluster tool 100, according to one or more embodiments of the present disclosure. The multi-chamber cluster tool 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the multi-chamber cluster tool 100 can be processed in and transferred between the various chambers without exposing the substrates to an ambient environment exterior to the multi-chamber cluster tool 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the multi-chamber cluster tool 100. Accordingly, the multi-chamber cluster tool 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

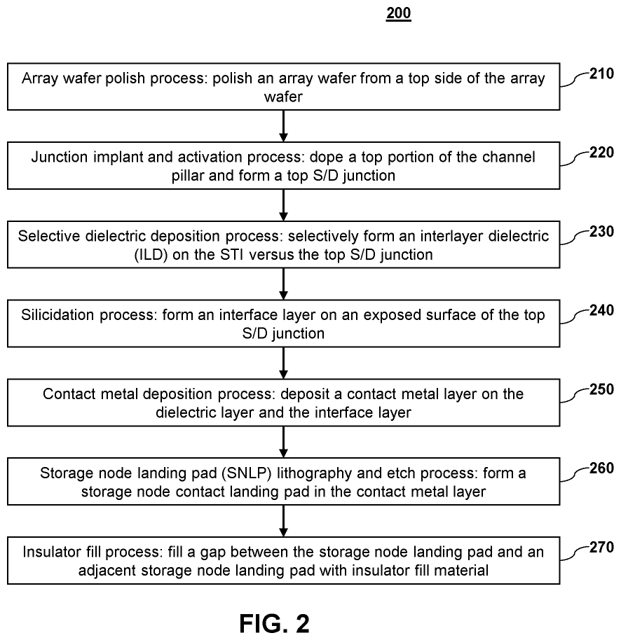

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, and the processing chambers 126, 128, 130 can be capable of performing respective epitaxial growth processes. The processing chamber 120 may be a Selectra™ Etch chamber available from Applied Materials of Santa Clara, Calif. The processing chamber 122 may be an Aktiv™ Pre-clean (APC) chamber, a Pre-clean XT (MCxT-2) chamber, or a SiCoNi™ Pre-clean chamber, available from Applied Materials of Santa Clara, Calif. The processing chamber 124, 126, 128, or 130 may be a Centura™ Epi chamber, a Volta™ CVD/ALD chamber, an Encore™ PVD chamber, a selective tungsten deposition chamber, an ionized metal plasma physical vapor deposition (IMP PVD) chamber, a rapid thermal process (RTP) chamber, or a plasma etch (PE) chamber, available from Applied Materials of Santa Clara, Calif. A system controller 168 is coupled to the multi-chamber cluster tool 100 for controlling the multi-chamber cluster tool 100 or components thereof. For example, the system controller 168 may control the operation of the multi-chamber cluster tool 100 using a direct control of the chambers 104, 106, 108, 110, 116, 118, 120, 122, 124, 126, 128, 130 of the multi-chamber cluster tool 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the multi-chamber cluster tool 100. The system controller 168 is configured to cause the chambers 104, 106, 108, 110, 116, 118, 120, 122, 124, 126, 128, 130 of the multi-chamber cluster tool 100 to perform all of the operations described with respect to FIG. 2.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

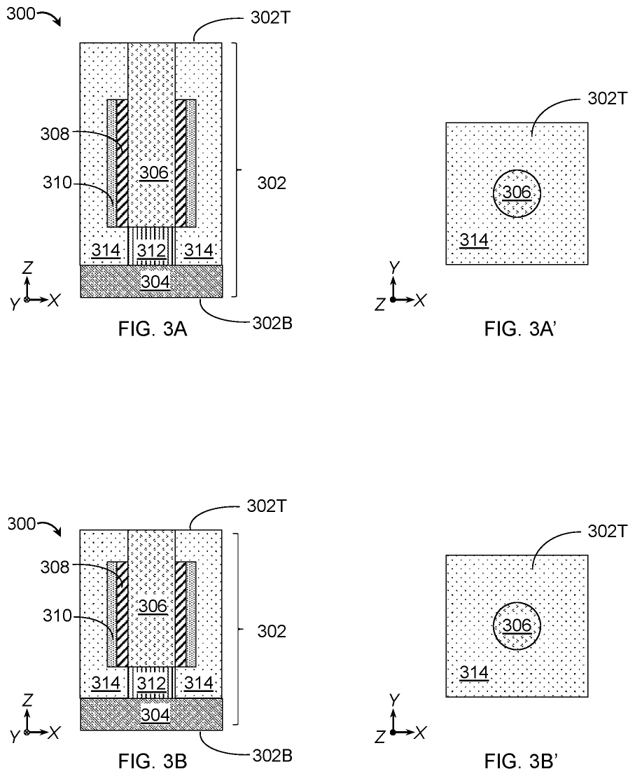

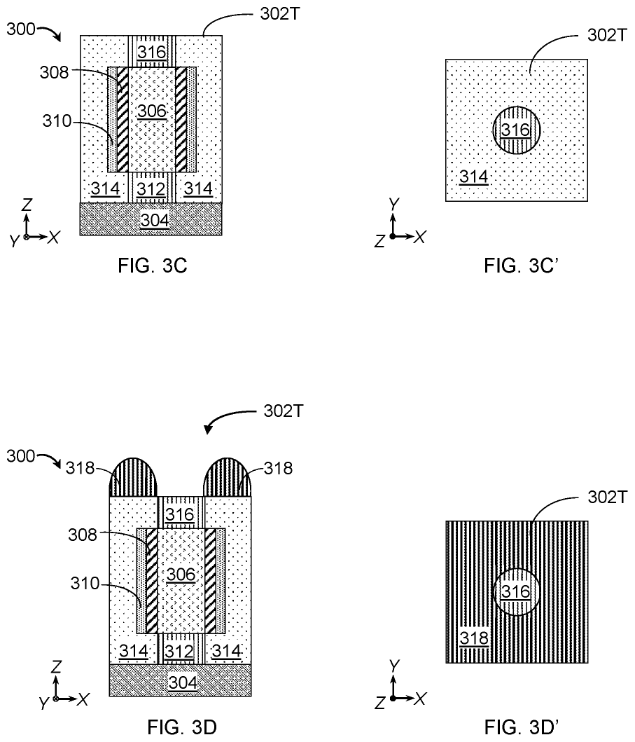

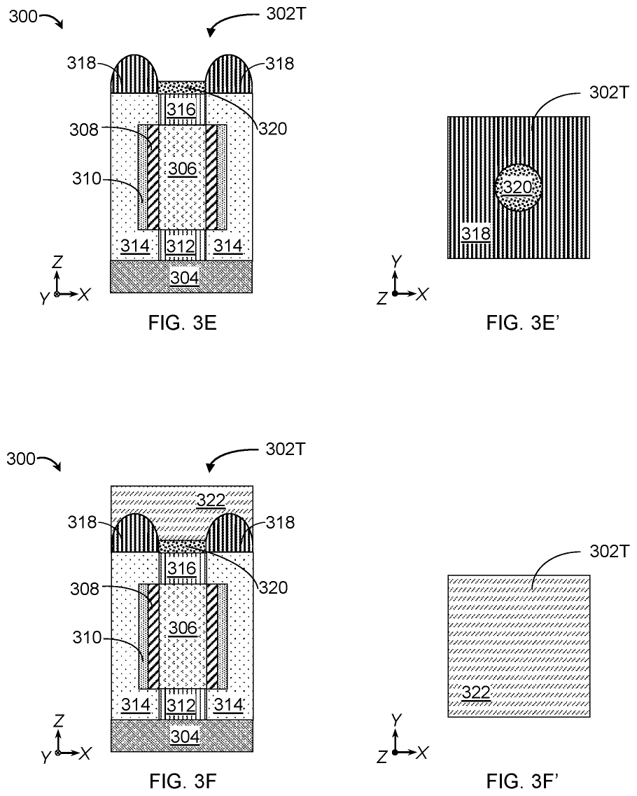

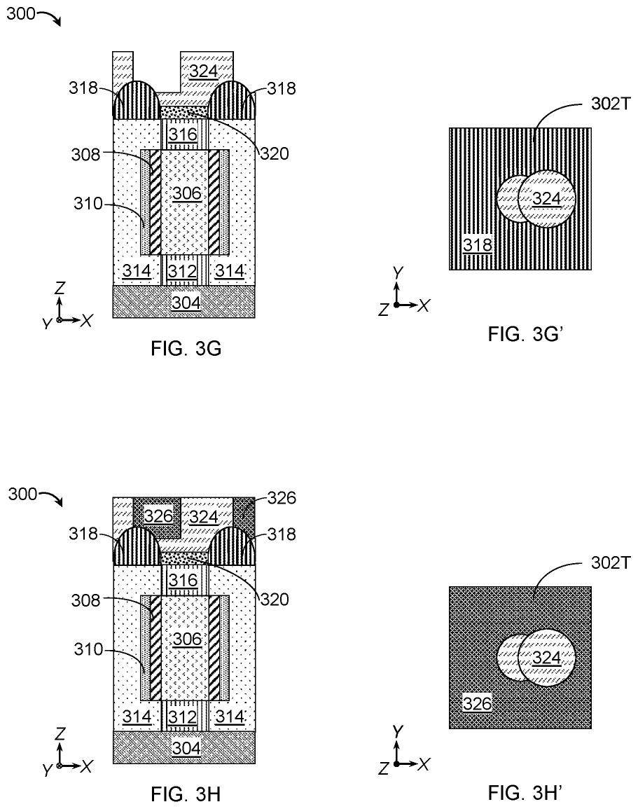

FIG. 2 is a process flow diagram of a method 200 of forming a self-aligned storage node contact (SNC) in a vertical channel structure 300, according to one or more implementations of the present disclosure. FIGS. 3A, 3B, 3C, 3D, 3E, 3F, 3G, and 3H are cross-sectional views of a portion of the vertical channel structure 300 corresponding to various stages of the method 200. FIGS. 3A′, 3B′, 3C′, 3D′, 3E′, 3F′, 3G′, and 3H′ are top-down views of the portion of the vertical channel structure 300. The vertical channel structure 300 may be a vertical array transistor portion of a 4F² dynamic random access memory (DRAM) device. It should also be understood that the operations depicted in FIG. 2 may be performed simultaneously and/or in a different order than the order depicted in FIG. 2.

In a vertical array transistor used in a 4F² dynamic DRAM device, source/drain (S/D) junctions are disposed on top and at bottom of a channel pillar, and dielectric material is filled between adjacent vertical array transistors as a shallow trench isolation (STI). The bottom S/D junction is electrically connected to a bitline and the top S/D junction is electrically connected to a storage capacitor in a 4F² DRAM device via a storage node contact (SNC).

As shown in FIGS. 3A and 3A′, the vertical channel structure 300 includes an array wafer 302 including a bitline layer 304 extending in the X direction, a channel pillar 306 over the bitline layer 304 and surrounded by a gate oxide layer 308, a word line layer 310 extending in the Y direction on both sides of the channel pillar 306 in the X direction, and a bottom source/drain (S/D) junction 312 that electrically connects the channel pillar 306 to the bitline layer 304, disposed within a shallow trench isolation (STI) 314 (also referred to as a “dielectric region”). A bottom side 302B of the array wafer 302 may be bonded to a carry wafer (not shown).

The bitline layer 304 and the word line layer 310 may be formed of tungsten (W), cobalt (Co), ruthenium (Ru), molybdenum (Mo), titanium nitride (TiN), iridium (Ir), tantalum (Ta), tantalum nitride (TaN), platinum (Pt), rhodium (Rh), or conductive oxides or nitrides thereof, or any combination thereof. The word line layer 310 may have a thickness on each side of the channel pillar 306 of between about 4 nm and about 6 nm, for example, about 4 nm.

The channel pillar 306 may be formed of silicon (Si), germanium (Ge), silicon germanium (SiGe), or indium gallium zinc oxide (IGZO), and have a diameter of between about 5 nm and about 10 nm, for example, about 10 nm. The channel pillar 306 may be spaced from an adjacent channel pillar (not shown) by a spacing of between about 18 nm and about 25 nm, for example, about 20 nm.

The gate oxide layer 308 may be formed of silicon oxide (SiO₂), silicon oxynitride (SiON), a high-K dielectric material, such as hafnium oxide (HfO₂), zirconium oxide (ZrO₂), aluminum oxide (Al₂O₃), hafnium silicon oxide (HfSiO), zirconium silicon oxide (ZrSiO), tantalum pentoxide (Ta₂O₅), tantalum silicon oxide (TaSiO), or any combination thereof, and have a thickness in the X direction of between about 3 nm and about 4 nm.

The bottom S/D junction 312 may be formed of silicon (Si), germanium (Ge), silicon germanium (SiGe), or indium gallium zinc oxide (IGZO), doped with n-type dopants, such as phosphorus (P), arsenic (As), or antimony (Sb), or p-type dopants, such as boron (B) or gallium (Ga), with a concentration of between about 10¹⁹ cm⁻³ and 5×10²⁰ cm⁻³, depending upon the desired conductive characteristic of the bottom S/D junction 312. The bottom S/D junction 312 may have a depth in the Z direction of between about 15 nm and about 35 nm.

The STIs 314 may be formed of silicon oxide (SiO₂).

The method 200 begins in block 210, in which an array wafer polish process is performed to polish the array wafer 302 from a top side 302T of the array wafer 302, as shown in FIG. 3B. The array wafer polish process may include a chemical mechanical polishing (CMP) process to thin the array wafer 302 to a desired height from the bitline layer 304, for example, between about 180 nm and about 200 nm.

In block 220, a junction implant and activation process is performed to dope a top portion of the channel pillar 306 and form a top S/D junction 316, as shown in FIG. 3C. The top S/D junction 316 is electrically connectible to a storage capacitor in a 4F₂ DRAM device via a storage node contact (SNC) to be formed in the following fabrication steps. The junction implant and activation process may include ion implantation of n-type dopants, such as phosphorus (P), arsenic (As), or antimony (Sb), from the top side 302T of the array wafer 302. The top S/D junction 316 may have a depth in the Z direction of between about 15 nm and about 35 nm.

In block 230, a selective dielectric deposition process is performed to selectively form an interlayer dielectric (ILD) 318 on the STI 314 (e.g., silicon oxide (SiO₂)) versus the top S/D junction 316 (e.g., silicon (Si)), as shown in FIG. 3D.

The ILD 318 may be formed of dielectric material, such as aluminum oxide (Al₂O₃), hafnium oxide (HfO₂), titanium oxide (TiO₂), zinc oxide (ZnO), or indium oxide (In₂O₃), and have a thickness of between about 20 nm and about 30 nm.

The selective dielectric deposition process may include surface termination and passivation of an exposed surface of the top S/D junction 316 (e.g., silicon (Si)) prior to deposition of the ILD 318 on an exposed surface of the STI 314 (e.g., silicon oxide (SiO₂)) by any appropriate deposition process, such as atomic layer deposition (ALD), performed in a processing chamber, such as the processing chamber 126, 128, or 130 shown in FIG. 1. The surface termination and passivation may be hydrogen termination of the top S/D junction 316 (e.g., silicon (Si)) to suppress growth of oxide (e.g., silicon oxide (SiO₂)) on the surface of the top S/D junction 316 (e.g., silicon (Si)). Any growth of the ILD 318 on the unwanted regions (e.g., on the top S/D junction 316) is removed by a post deposition cleaning process, such as wet etching.

In some embodiments, the selective dielectric deposition process includes a cycle of a conformal chemical vapor deposition (CVD) of the ILD 318, performed in a processing chamber, such as the processing chamber 126, 128, or 130 shown in FIG. 1, and an etch process, such as wet etching, performed in a processing chamber, such as the processing chamber 122 shown in FIG. 1, to remove any growth of the ILD 318 on the unwanted regions (e.g., on the top S/D junction 316). The cycle of the conformal deposition process and the etch process may be repeated as needed to obtain a desired thickness of the ILD 318 on the surface of the STI 314.

In some embodiments, the selective dielectric deposition process includes inhibitor adsorption and re-adsorption to deposit inhibitor, such as a self-assembled monolayer (SAM) of organic molecules, such as methane (CH₄), or a thin layer of dielectric material, such as silicon dioxide (SiO₂), silicon nitride (Si₃N₄), silicon carbonitride (SiCN), silicon oxycarbide (SiOC), or silicon oxynitride (SiON), or a combination thereof, on the exposed surface of the top S/D junction 316 (e.g., silicon (Si)), to prevent any growth of the ILD 318 on the top S/D junction 316.

In block 240, a silicidation process is performed to form an interface layer 320 on the exposed surface of the top S/D junction 316, as shown in FIG. 3E.

The interface layer 320 may be formed of metal silicide, such as nickel silicide (NiSi), tungsten silicide (WSi₂), molybdenum silicide (MoSi₂), titanium silicide (TiSi₂), cobalt silicide (CoSi₂), tantalum silicide (TaSi₂), or any combination thereof, with a thickness of between about 5 nm and about 10 nm. The interface layer 320 may lower the resistance of the top S/D junction 316.

The silicidation process may include any appropriate deposition process, such as such as chemical vapor deposition (CVD), physical vapor deposition (PVD), or the like performed in a processing chamber, such as the processing chamber 126, 128, or 130 shown in FIG. 1.

In block 250, a contact metal deposition process is performed to deposit a contact metal layer 322 on the ILD 318 and the interface layer 320, as shown in FIG. 3F.

The contact metal layer 322 may be formed of tungsten (W), titanium (Ti), ruthenium (Ru), molybdenum (Mo), copper (Cu), cobalt (Co), nickel (Ni), silver (Ag), gold (Au), iridium (Ir), tantalum (Ta), platinum (Pt), conductive oxides or nitrides thereof, or any combination thereof, and may have a thickness of between about 20 nm and about 30 nm.

The contact metal deposition process may include any appropriate deposition process, such as such as chemical vapor deposition (CVD), physical vapor deposition (PVD), or the like performed in a processing chamber, such as the processing chamber 126, 128, or 130 shown in FIG. 1.

In block 260, a storage node landing pad (SNLP) lithography and etch process is performed to form a storage node landing pad 324 in the contact metal layer 322, as shown in FIG. 3G.

The storage node landing pad 324 may have a width of less than about 20 nm and spaced from an adjacent storage node landing pad 324 by a spacing of more than about 14 nm.

The SNLP lithography and etch process may include any patterning technique, such as a lithography and etch process in a processing chamber, such as the processing chamber 120, 122, or 124 shown in FIG. 1.

In block 270, an insulator fill process is performed to fill a gap between the storage node landing pad 324 and an adjacent storage node landing pad 324 with insulator fill material 326, as shown in FIGS. 3H and 3H′. The interface layer 320 surrounded by the ILD 318, the contact metal layer 322, and the storage node landing pad 324 form a storage node contact (SNC) that electrically connects the top S/D junction 316 to a storage capacitor in a 4F² DRAM device.

The insulator fill material 326 may be silicon oxide (SiO₂), silicon nitride (Si₃N₄), silicon carbonitride (SiCN), or any combination thereof.

The metal fill process may include any appropriate deposition process, such as chemical vapor deposition (CVD), atomic layer deposition (ALD), physical vapor deposition (PVD), or the like, in a processing chamber, such as the processing chamber 126, 128, or 130 shown in FIG. 1.

In the embodiments described herein, methods of forming a self-aligned storage node contact (SNC) in a semiconductor device, such as a vertical channel structure used in a 4F² dynamic random access memory (DRAM) device, are provided. In the methods described herein, an interlayer dielectric (ILD) surrounding a surface of a vertical array transistor is formed in a self-aligned process by selective dielectric deposition, and thus fabrication of a storage node contact (SNC) including such ILD does not require complex and costly lithography processes or selective epitaxy growth of silicon.

While the foregoing is directed to embodiments of the present disclosure, other and further embodiments of the disclosure may be devised without departing from the basic scope thereof, and the scope thereof is determined by the claims that follow.

1. A method for forming a storage node contact in a dynamic random access memory (DRAM) device, comprising:
performing an array wafer polish process to polish an array wafer from a top side of the array wafer, the array wafer comprising a bitline layer, a channel pillar over the bitline layer and surrounded by a gate oxide layer, a word line layer on both sides of the channel pillar, and a bottom source/drain (S/D) junction that electrically connects the channel pillar to the bitline layer, disposed within a shallow trench isolation (STI);
performing a junction implant and activation process to dope a top portion of the channel pillar and form a top S/D junction;
performing a selective dielectric deposition process to selectively form an interlayer dielectric (ILD) on the STI versus the top S/D junction;
performing a silicidation process to form an interface layer on an exposed surface of the top S/D junction;
performing a contact metal deposition process to deposit a contact metal layer on the ILD and the interface layer;
performing a storage node landing pad (SNLP) lithography and etch process to form a storage node landing pad in the contact metal layer; and
performing an insulator fill process to fill a gap between the storage node landing pad and an adjacent storage node landing pad with insulator fill material.

2. The method of claim 1, wherein the channel pillar comprises silicon (Si), and the STI comprises silicon oxide (SiO₂).

3. The method of claim 1, wherein the channel pillar has a diameter of between 5 nm and 10 nm, and is spaced from an adjacent channel pillar by a spacing of between 18 nm and 25 nm.

4. The method of claim 1, wherein the ILD comprises aluminum oxide (Al₂O₃), hafnium oxide (HfO₂), titanium oxide (TiO₂), zinc oxide (ZnO), or indium oxide (In₂O₃).

5. The method of claim 1, wherein the ILD has a thickness of between about 20 nm and about 30 nm.

6. The method of claim 1, wherein the selective dielectric deposition process comprises hydrogen termination of the exposed surface of the top S/D junction and atomic layer deposition (ALD) of the ILD on an exposed surface of the STI.

7. The method of claim 1, wherein the selective dielectric deposition process comprises a conformal chemical vapor deposition (CVD) of the ILD and an etch process to remove any growth of the ILD on the top S/D junction.

8. The method of claim 1, wherein the interface layer comprises nickel silicide (NiSi), tungsten silicide (WSi₂), molybdenum silicide (MoSi₂), titanium silicide (TiSi₂), cobalt silicide (CoSi₂), tantalum silicide (TaSi₂), or any combination thereof.

9. The method of claim 1, wherein the contact metal layer and the landing pad each comprise tungsten (W), titanium (Ti), ruthenium (Ru), molybdenum (Mo), copper (Cu), cobalt (Co), nickel (Ni), silver (Ag), gold (Au), iridium (Ir), tantalum (Ta), platinum (Pt), conductive oxides or nitrides thereof, or any combination thereof.

10. The method of claim 1, wherein the storage node landing pad has a width of less than 20 nm and spaced from an adjacent storage node landing pad by a spacing of more than 14 nm.

11. A method for forming a self-aligned interlayer dielectric (ILD) in a vertical channel structure, comprising:
selectively depositing an ILD on a dielectric region versus an exposed surface of a channel pillar disposed within the dielectric region, wherein:
the dielectric region comprises silicon oxide (SiO₂), and
the channel pillar comprises silicon (Si).

12. The method of claim 11, wherein the channel pillar has a diameter of between 5 nm and 10 nm, and is spaced from an adjacent channel pillar by a spacing of between 18 nm and 25 nm.

13. The method of claim 11, wherein the ILD comprises aluminum oxide (Al₂O₃), hafnium oxide (HfO₂), titanium oxide (TiO₂), zinc oxide (ZnO), or indium oxide (In₂O₃).

14. The method of claim 11, wherein the ILD has a thickness of between about 20 nm and about 30 nm.

15. The method of claim 11, wherein the depositing of the ILD comprises hydrogen termination of the exposed surface of the channel pillar, atomic layer deposition (ALD) of the ILD on an exposed surface of the dielectric region, and wet etching to remove any growth of the ILD on the exposed surface of the channel pillar.

16. The method of claim 11, wherein the depositing of the ILD comprises a cycle of a conformal chemical vapor deposition (CVD) of the ILD, and an etch process to remove any growth of the ILD on the exposed surface of the channel pillar.

17. The method of claim 11, wherein the depositing of the ILD comprises inhibitor adsorption and re-adsorption to deposit inhibitor to deposit inhibitor on the exposed surface of the channel pillar.

18. A vertical channel structure, comprising:
a bitline layer extending in a first direction;
a word line layer extending in a second direction that is orthogonal to the first direction;
a vertical array transistor disposed within a shallow trench isolation (STI), the vertical array transistor comprising a channel pillar, a bottom source/drain (S/D) junction electrically connected to the bitline layer, and a top S/D junction connectible to a storage capacitor via a storage node contact, wherein the storage node contact comprises:
an interface layer on a surface of the top S/D junction surrounded by a self-aligned interlayer dielectric (ILD) on a surface of the STI;
a contact metal layer on the interface layer and the ILD; and
a landing pad within the contact metal layer.

19. The vertical channel structure of claim 18, wherein:
the channel pillar comprises silicon (Si), and the STI comprises silicon oxide (SiO₂), and
the channel pillar has a diameter of between 5 nm and 10 nm, and is spaced from an adjacent channel pillar by a spacing of between 18 nm and 25 nm.

20. The vertical channel structure of claim 18, wherein the self-aligned ILD comprises aluminum oxide (Al₂O₃), hafnium oxide (HfO₂), titanium oxide (TiO₂), zinc oxide (ZnO), or indium oxide (In₂O₃).
